(19) United States
(12) Patent Application Publication
(10) Pub. No.: US 2009/0189269 A1
(43) Pub. Date: Jul. 30, 2009

(54) Electronic Circuit Package

(76) Inventors: Lap-Wai Lydia Leung, Hong Kong (CN); Chang Hwa Chung, Hong Kong (HK); Jie Liu, Hong Kong (HK); Chi Kuen Leung, Hong Kong (CN); Chiu Lun Chan, Hong Kong (HK)

Correspondence Address: WELLS ST. JOHN P.S., 601 W. FIRST AVENUE, SUITE 1300, SPOKANE, WA, 99201, US

(21) Appl. No.: 12/019,413

(22) Filed: Jan. 24, 2008

(51) Int. Cl. H05K 1/00; H01L 23/48

(52) U.S. Cl. 257/690; 361/749; 257/E23.01

(57) ABSTRACT

A electronic circuit package having a flexible substrate with metals layers on one or more of its surfaces forming a wiring pattern and/or surface mount bonding pads. Passive electronic components are integrated onto component packages that are mounted to the flexible substrate and electrically connected with the wiring pattern or bonding pad. An active electronic device is mounted on the flexible substrate or bonding pad.

### BACKGROUND TO THE INVENTION

1. Field of the Invention

The current invention relates to electronic circuit packages and in particular to substrates for holding both passive and active electronic circuit components. The invention also relates to radio-frequency front end modules and to electronic equipment incorporating such packages and modules.

2. Background Information

Modern electronic devices are characterised by small size and large functionality. Consumers desire products with more and more functions, but without compromising on size and weight. Such devices are also characterised by wireless interconnectivity for communicating, sharing or downloading information. In response, electronic designers are continually striving to make smaller more efficient electronic circuit packages. However, various design considerations such as track/interconnect routing, parasitics, losses and heating affect the size and form-factor of electronic packages, particularly in radio-frequency applications. Another aspect that affects size and form-factor is the number of passive circuit component in modern electronic circuitry. Modern electronic circuits contain a large number of semiconductor integrated circuit (IC) devices, however it is estimated there between 60-70% of components in modern electronic circuits are discrete passive components.

One attempt to improve electronic packaging, particularly for a wireless device, is disclosed in U.S. Pat. No. 7,148,751. This patent describes a radio-frequency front end module having both passive and active components incorporated into a single module in order to provide a more efficient and reliable module that is smaller, lighter, costs less and has fewer interconnects. The package is based around a lead-frame skeleton.

Another attempt to improve electronic packaging is disclosed in U.S. Pat. No. 7,127,269. This patent describes a front-end module including a switch, two channel-separating devices, a plurality of band-pass filters, a plurality of baluns, and a plurality of low-pass filters integrated into a Low Temperature Co-fired Ceramic (LTCC) package by a patterning process.

Yet another attempt to improve electronic packaging is disclosed in U.S. Pat. No. 6,236,271, which describes a single multi-layer carrier module which carries the power amplifier components for a GSM mobile telephone. The package incorporates the power amplifier and power amplifier controllers in a rigid laminate package.

Various problems are associated with the use of lead-frames, LTCC and rigid laminate packages. Lead-frame packages are limited to a single layer which limits routing flexibility, and hence form factor, and placement of active dies and integrate passive devices. Typically, the minimum achievable thickness of a lead-frame package about is 0.5 mm. Although modern techniques such as LTCC and thin-film are used to reduce the size of passive components about 10-20 layers are needed to integrate passive components into a substrate and so again the typical minimum achievable thickness of an integrate LTCC package about is 0.5 mm-0.6 mm. The surface topology of LTCC also creates assembly problems. While rigid laminate substrates can be as thin as 0.25 mm the inclusion of surface mount electronic components more than doubles the package thickness.

Thus there exists a need for an improved electronic circuit packages by making thinner, smaller, lighter and more efficient.

### SUMMARY OF THE INVENTION

Accordingly, it is an object of the present invention to provide a smaller, lighter electronic circuit package, and in particular a radio-frequency front end module, that overcomes or ameliorates at least some of the disadvantages with the prior art or at least provides the public with a useful alternative.

There is disclosed herein an electronic circuit package comprising a flexible substrate. The flexible substrate has metals layers formed or deposited on one or more of its surfaces to produce a wiring pattern and/or a surface mount bonding pad. An integrated component package is mounted to the flexible substrate and electrically connected with the wiring pattern or bonding pad. The integrated component package comprises two or more electronic components. A surface-mount electronic device is mounted on the flexible substrate or bonding pad.

The electronic component package and/or electronic device may both of a surface-mount type.

The electronic components can comprise passive devices integrated into the component package to form one or more of a filter, a balun or an impedance matching network for integration into the flexible circuit.

The surface-mount electronic device can comprise a semiconductor chip device or packaged integrated-circuit and is preferably selected from a group consisting of a radio-frequency die, a low-noise amplifier, a power amplifier and a switch.

The electronic circuit package may be made rigid by providing an encapsulating material on the flexible substrate and encapsulating material encapsulating the electronic component package and the electronic device.

Further aspects of the invention will become apparent from the following description which is given by way of example only.

### BRIEF DESCRIPTION OF THE DRAWINGS

FIG. 1 is a side schematic view of the package, and

FIG. 2 is a schematic overview of an electronic circuit package according to the invention.

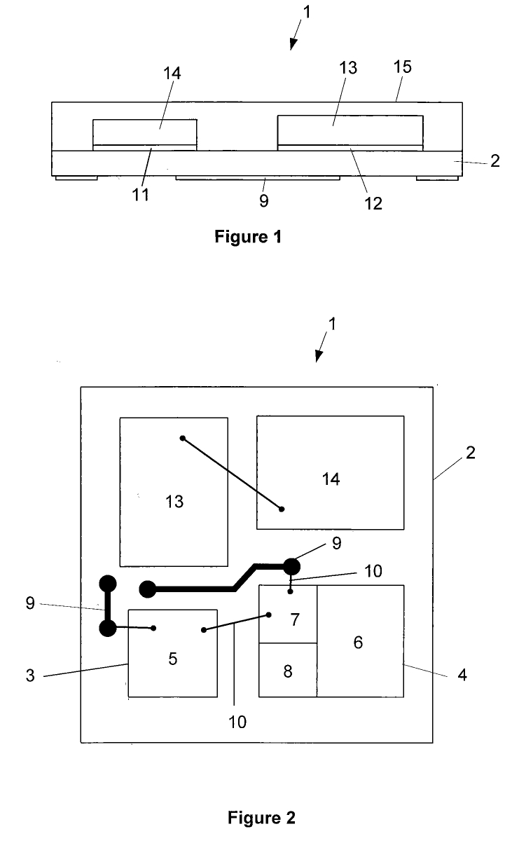

### DETAILED DESCRIPTION OF THE EXEMPLARY EMBODIMENTS

The current invention utilizes flexible electronics, also known as flex-circuits or flex circuit boards, in which a thin flexible plastic sheet is used as a supporting substrate instead of traditional rigid substrates. Typically the plastic is a polymer such as polyimide. The flexible substrate has metal layers formed on one or more of its, upper and lower, surfaces from which a wiring pattern and/or bonding pads are formed. The invention also integrates passive electronic components together into one or more small electronic component packages by thin-film techniques. The component packages are then mounted to the flexible substrate and connected with the wiring pattern or bonding pads. One or more active components are mounted to the flexible substrate in electrical connection with the wiring pattern and thus components integrated into a component package. In the preferred embodiment the electronic component packages and active devices can be mounted to the flexible substrate using surface-mount techniques, such as by a land grid array (LGA). The integrated components, active components and wiring pattern form a functioning electronic circuit, such as for example, a radio-frequency front end module. Flexible substrates can be made very thin, typically less than 0.15 mm, and by forming wiring patterns on both sides of the substrate better track routing and component layout is achieved making for a much small package in height, width and thickness. The substrate can be covered in an inflexible encapsulating material to encapsulate and protect the packages and devices and make the final package rigid.

The invention will now be described as practiced in a radio-frequency front end module. However, this is not intended to limit the scope of use or functionality of the invention and those skilled in the art should realize that the invention can be worked in any electronic circuit comprising both passive and active components formed into a single package.

Referring to the drawings, in an exemplified embodiment of the invention there is an electronic package 1 comprising a flexible polyimide supporting substrate 2 having a wiring pattern 9 and bonding pads 11, 12 formed on its upper and lower surfaces from metal layers. The bonding pads 11, 12 may be any surface mount bonding arrangement but in the preferred embodiment are land grid arrays (LGAs). The wiring patterns form high density 50Ω transmission lines. The metal layers may or may not be flexible with the substrate.

A plurality of component packages 3, 4 are mounted onto the substrate 2. The component packages 3, 4 are formed by known thin-film techniques and comprise single or a plurality of passive electronic components arranged to form a filter 14, a balun 6, output impedance matching network 7 and decoupling capacitors 8. In the preferred embodiment the component packages 3, 4 are mounted directly to the flexible substrate with adhesive or the like and are electronically connected with the wiring pattern by bonding wires 10. In an alternative embodiment however the component packages 3, 4 may be made as passive surface-mount devices for mounting to a bonding pad of the flexible substrate.

To complete the functional electrical circuit of the RF module two active electronic devices 5, 13 are mounted to the bonding pads 11, 12 on the flexible substrate. The active devices include a power amplifier 13 and a switch 5. To complete the package and protect the active components the top surface of the flexible substrate 2 is encapsulated in an inflexible non-conductive bonding material 15.

The completed RF module can be incorporated into electric equipment such as mobile telephones and other wireless devices.

Advantages of the invention over the prior art include that the flexible substrate is up to 50% thinner than rigid substrates. The flexible substrate may be thinner than 0.15 mm. Passive components are integrated into functional component packages which are then mounted on to the flexible substrate thus reducing the number of discrete passive components to be mounted onto the flexible substrate. These integrated passive component packages made by thin film techniques can be up to one-third thinner than individual discrete components made to standard 0201 passives and allow for easier manufacturing and wiring pattern/tack layout. The integrated passive component packages may be as thin as 175 μm as compared with 300 μm for standard 0201 passives. The thin flexible substrate and integrated passives allow for narrow 50Ω transmission lines to be achieved in the wiring pattern. Finally, encapsulating the package in an inflexible material makes it rigid and protects the module from mechanical stresses etc. The result of the above is a smaller, cheaper, more easily manufactured electronic circuit package for inclusion within electronic devices.

Another aspect of the invention is integrating multiple passive components into a single component package. This reduces the number of bonding wire and external connections to passive devices, which improves performance and reduces interference in high frequency applications such as radio-frequency front end modules.

It should be appreciated that modifications and/or alterations obvious to those skilled in the art are not considered as beyond the scope of the present invention.

What is claimed is:

1. An electronic circuit package comprising:
a flexible substrate,
an electronic component package mounted on the flexible substrate, the electronic component package comprising two or more electronic components integrated into the package, and
a electronic device mounted on the flexible substrate and electrically connected with the electronic component package.

2. The package of claim 1 further comprising a wiring pattern formed on the flexible substrate, the electronic component package and the electronic device both being electrically connected with the wiring pattern.

3. The package of claim 1 wherein the electronic component package and electronic device are both of a surface-mount type.

4. The package of claim 1 wherein the electronic component package is an integrated thin-film circuit.

5. The package of claim 1 wherein the two or more electronic components are passive electronic devices.

6. The package of claim 1 wherein the electronic device comprises a semiconductor chip device or packaged integrated-circuit.

7. The package of claim 6 wherein the semiconductor chip device is selected from a group comprising of a radio-frequency die, a low-noise amplifier, a power amplifier and a switch.

8. The package of claim 1 wherein the flexible substrate has a thickness of no more than 0.15 mm.

9. The package of claim 1 wherein the wiring pattern comprises a bonding pad for mounting the electronic component package and the electronic device.

10. The package of claim 1 wherein the flexible substrate has first and second surfaces with the wiring pattern formed on both the first and second surfaces, and further includes interconnects through the flexible substrate to electrically connect the wiring patterns on the first and second surfaces.

11. The package of claim 1 further included an encapsulating material provided on the flexible substrate, the encapsulating material encapsulating the electronic component package and the electronic device.

12. The package of claim 11 wherein the encapsulating material is inflexible in a set state so that the electronic circuit package is rigid.

13. A radio-frequency front end module comprising of the electronic circuit package of claim 1.

14. Electronic equipment comprising the electronic circuit package of claim 1.

15. An electronic circuit package comprising:
a flexible substrate having first and second surfaces and a wiring pattern formed on at least the first surface,
an electronic component package mounted to the flexible substrate and electrically connected with the wiring pattern, said electronic component package comprising two or more electronic components integrated into the electronic component package, and
a surface-mount electronic device mounted on the flexible substrate and electrically connected with the wiring pattern, said surface-mount electronic device comprising a semiconductor chip device or packaged IC

16. The package of claim 15 wherein the flexible substrate has a thickness of less than 0.5 mm.

17. The package of claim 15 wherein the electronic component package is an integrated thin-film circuit and the electronic components are passive electronic devices.

18. The package of claim 15 wherein the wiring pattern is formed by a metal layer deposited on the first and/or second surfaces of the flexible substrate.

19. An electronic package comprising:
a flexible substrate having a thickness of less than 0.15 mm and a wiring pattern formed thereon,
one or more passive electronic components integrated into a component package, the component package mounted to the flexible substrate and electrically connected with the wiring pattern, and
an active electronic device mounted on the flexible substrate and electrically connected with the wiring pattern.

20. The package of claim 19 further including an inflexible encapsulating material provided on the flexible substrate, the encapsulating material encapsulating the electronic component package and the electronic device.

21. The package of claim 19 wherein the component packages is a thin-film electronic circuit.

22. The package of claim 19 wherein the flexible substrate has first and second surfaces with the wiring pattern is formed on both the first and second surfaces.

23. A radio-frequency front end module comprising:
a flexible substrate having a wiring pattern formed thereon,
two or more integrated electronic devices mounted to the flexible substrate and electrically connected with the wiring pattern, the integrated electronic devices selected from a group comprising a filter, a balun or an impedance matching network, and
a surface-mount radio-frequency die mounted on the flexible substrate and electrically connected with the wiring pattern.

24. The radio-frequency front end module of claim 23 further included an inflexible encapsulating material provided on the flexible substrate, the encapsulating material encapsulating the passive electronic devices and the radio-frequency die.

25. A wireless electronic device comprising the radio-frequency front end module of claim 24.
